(19) United States
(12) Patent Application Publication
(10) Pub. No.: US 2026/0229262 A1
(43) Pub. Date: Aug. 6, 2026

(54) SINGLE ENDED MEMORY SENSING ARCHITECTURE

(71) Applicant: Texas Instruments Incorporated, Dallas, TX (US)

(72) Inventors: Premkumar Seetharaman, Bangalore (IN); Narasimha Reddy, Bangalore (IN)

(21) Appl. No.: 19/042,617

(22) Filed: Jan. 31, 2025

(51) Int. Cl. G11C 7/12

(52) U.S. Cl. CPC G11C 7/12

(57) ABSTRACT

A semiconductor device includes a data bit line coupled to bit cells. A data pre-charge variable current source is structured to provide a first data pre-charge current to the data bit line, and to provide a second data pre-charge current to the data bit line that is less than the first data pre-charge current. A dummy pre-charge current source is structured to provide a dummy pre-charge current to a dummy bit line through a dummy current line. A threshold detector is structured to provide a threshold signal when the dummy current line reaches a threshold potential. A pre-charge controller is structured to cause the first data pre-charge current to be provided to the data bit line prior to receiving the threshold signal, and the second data pre-charge current after receiving the threshold signal. A sense amplifier includes an input inverter stage having a positive feedback loop.

### TECHNICAL FIELD

This disclosure relates to the field of semiconductor devices. More particularly, but not exclusively, this disclosure relates to memory circuits in semiconductor devices.

### BACKGROUND

Memory components in modern electronic devices provide data storage. As operating speeds of semiconductor devices increase over time, there is a need to reduce the time required to read data from the memory components. Reducing the read time, while meeting concurrent goals of power and device area, is challenging.

### SUMMARY

The present disclosure introduces a semiconductor device that includes a memory array. The memory array includes bit cells and a data bit line coupled to the bit cells.

In one aspect, the semiconductor device includes a data pre-charge variable current source coupled to the data bit line. The data pre-charge variable current source is structured to provide a first data pre-charge current to the data bit line, and to provide a second data pre-charge current to the data bit line that is less than the first data pre-charge current.

The semiconductor device also includes a dummy bit line. The semiconductor device further includes a dummy pre-charge current source coupled to the dummy bit line through a dummy current line. The dummy pre-charge current source is structured to provide a dummy pre-charge current to the dummy bit line through the dummy current line. The semiconductor device includes a threshold detector connected to the dummy bit line. The threshold detector is structured to provide a threshold signal when a dummy bit line potential on the dummy bit line reaches a threshold potential.

The semiconductor device includes a pre-charge controller connected to the threshold detector, the data pre-charge variable current source, and the dummy pre-charge current source. The pre-charge controller is structured to cause the data pre-charge variable current source to provide the first data pre-charge current to the data bit line after receiving a start signal and prior to receiving the threshold signal. The pre-charge controller is also structured to cause the data pre-charge variable current source to provide the second data pre-charge current to the data bit line after receiving the threshold signal. The pre-charge controller is further structured to cause the dummy pre-charge current source to provide the dummy pre-charge current to the dummy bit line after receiving the start signal.

In another aspect, the semiconductor device includes a sense amplifier. The sense amplifier includes an input inverter stage having a signal input and a signal output. The signal input is coupled to the data bit line. The sense amplifier also includes a shunt switch connecting the signal input to a reference conductive structure. The shunt switch has a control node, which is structured to cause the shunt switch to vary an impedance of the shunt switch. The sense amplifier includes further includes a connection between the signal output and the control node.

### BRIEF DESCRIPTION OF THE FIGURES

FIG. 1 is a conceptual diagram of an example semiconductor device.

FIG. 2 is a chart of currents and potentials versus time for the semiconductor device of FIG. 1.

FIG. 3 is a schematic diagram of another example semiconductor device.

FIG. 4A through FIG. 4C are schematic diagrams of a further example semiconductor device.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A semiconductor device includes a memory array, such as a read-only memory. The memory array includes a column of bit cells. The memory array includes a data bit line coupled to the bit cells. The data bit line may be coupled to the bit cells through passgate switches, by way of example. The passgate switches may be structured to be controlled by word lines. Some of the bit cells are programmed, in which a terminal of the corresponding passgate switch is connected to a reference line. The reference line may be an element of a ground structure that includes a substrate of the semiconductor device and a ground line. The remaining bit cells are unprogrammed, in which the terminal of the corresponding passgate switch is not connected to the reference line. The terminals of the passgate switches of the unprogrammed bit cells may be floating, that is, the terminals are not directly conductively connected to any other conductive line.

In one aspect of this disclosure, the semiconductor device includes a dummy bit line. The dummy bit line may be coupled to a dummy bit cell through a dummy passgate switch. The dummy bit cell may be unprogrammed.

The semiconductor device includes a data pre-charge variable current source coupled to the data bit line. The data pre-charge variable current source is structured to provide a first data pre-charge current to the data bit line.

The semiconductor device also includes a dummy pre-charge current source coupled to the dummy bit line. The dummy pre-charge current source is structured to provide a dummy pre-charge current to the dummy bit line.

The semiconductor device further includes a pre-charge controller connected to the data pre-charge variable current source and the dummy pre-charge current source. The pre-charge controller is structured to cause the data pre-charge variable current source to provide the first data pre-charge current to the data bit line after receiving a start signal, and to cause the dummy pre-charge current source to provide the dummy pre-charge current to the dummy bit line after receiving the start signal.

The semiconductor device includes a threshold detector connected to the dummy bit line. The threshold detector is structured to provide a threshold signal to the pre-charge controller when a dummy bit line potential on the dummy bit line reaches a threshold potential. The pre-charge controller is further structured to cause the data pre-charge variable current source to provide a second data pre-charge current to the data bit line after receiving the threshold signal. The second data pre-charge current is less than the first data pre-charge current.

In another aspect, the semiconductor device includes a sense amplifier that is structured to provide a digital output corresponding to the state, that is, programmed or unprogrammed, of a bit cell being read. The sense amplifier includes an input inverter stage and an output inverter stage. The input inverter stage has a signal input and a signal output. The data bit line is coupled to the signal input. The sense amplifier also includes a shunt switch connecting the signal input to a reference conductive structure, such as a ground line. The shunt switch has a control node. The sense amplifier further includes a feedback connection between the signal output of the input inverter stage and the control node. The control node is structured to cause the shunt switch to vary an impedance of the shunt switch. The shunt switch has a transconductance polarity such that the feedback connection between the signal output of the input inverter stage and the shunt switch provides a positive feedback loop for the input inverter stage.

The sense amplifier further includes a weak holding shunt connected between the signal output of the input inverter stage and a reference line, such as a ground line.

A component such as a transconductor or a transistor that is disclosed as “structured to be controlled” by a signal has a control node connected to one or more circuits that provide the signal during operation of the semiconductor device. A control node may include a gate of a field effect transistor or a base of a bipolar junction transistor. Similarly, a component that is disclosed as “structured to receive” a signal has a control node connected to one or more circuits that provide the signal during operation of the corresponding semiconductor device. A component that is disclosed as “structured to provide” a signal is connected to one or more receiving elements, at a current node of the component. The receiving elements may be control nodes, such as a gates or bases, of transistors.

Transducers and transistors are disclosed as in an ON state or in an OFF state. Transducers and transistors in the ON state have lower impedances than in the OFF state, and thus may conduct more current than in the OFF state.

A component that is disclosed as coupled to, or connected to, another component, a power line, or a reference line, is structured to support direct current (DC) through the connection, between the component and the other component or the potential. Aspects of this disclosure which describe current flows and signal voltage transitions are related to operation of the semiconductor device. The current flows and signal voltage transitions are explained to assist understanding of the semiconductor device. Current flows and signal voltage transitions may not be present in the semiconductor device when the semiconductor device is not powered. A component that is disclosed as connected to an operational bias potential or a reference potential, is connected to one or more conductive elements of the semiconductor device that are structured to provide the potential(s) during operation of the semiconductor device.

One or more operational characteristics of various circuits, systems and/or components are hereinafter described in the context of functions which in some cases result from configuration and/or interconnection of various structures when circuitry is powered and operating. Various disclosed structures and methods of the present disclosure may be beneficially applied to manufactured electronic apparatus such as an integrated circuit. While such examples may be expected to provide various improvements, no particular result is a requirement of the present disclosure unless explicitly recited in a particular claim.

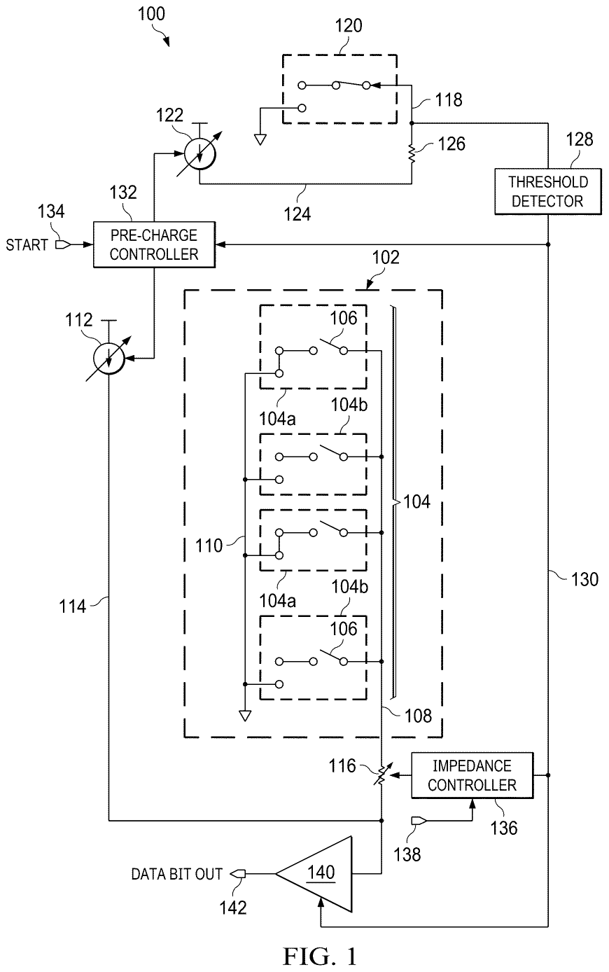

FIG. 1 is a conceptual diagram of an example semiconductor device. The semiconductor device 100 includes a memory array 102. The memory array 102 may be manifested as a read-only memory, by way of example. The memory array 102 includes a column of bit cells 104. Each bit cell 104 of this example includes a passgate switch 106 connected to a data bit line 108. Some of the bit cells 104a are programmed, in which a terminal of the passgate switch 106 of the programmed bit cell 104a is connected to a reference line 110, such as a ground line, as depicted schematically in FIG. 1. Other potentials for the reference line 110 are within the scope of this example. The remaining bit cells 104b are unprogrammed, in which the terminal of the corresponding passgate switch 106 is not connected to the reference line 110. The terminals of the passgate switches 106 in the unprogrammed bit cells 104b may be floating, that is, the terminals are not directly connected to any other conductive line.

The semiconductor device 100 includes a data pre-charge variable current source 112 coupled to the data bit line 108 through a data current line 114 in series with a data transfer gate 116, as depicted in FIG. 1. The data transfer gate 116 may have a variable impedance, as indicated in FIG. 1. The data pre-charge variable current source 112 is structured to provide a first data pre-charge current and a second data pre-charge current to the data bit line 108. The second data pre-charge current is less than the first data pre-charge current.

The semiconductor device 100 also includes a dummy bit line 118. The dummy bit line 118 may have a resistance, a capacitance, and an inductance similar to the data bit line 108. The semiconductor device 100 may include a dummy bit cell 120 coupled to the dummy bit line 118. The dummy bit cell 120 may have a structure similar to the unprogrammed bit cells 104b, that is, the dummy bit line 118 is not coupled to a reference line through the dummy bit cell 120.

The semiconductor device 100 includes a dummy pre-charge current source 122 coupled to the dummy bit line 118 through a dummy current line 124 in series with a dummy transfer gate 126, as indicated in FIG. 1. The dummy transfer gate 126 has a dummy impedance, which may be implemented as a fixed impedance, as indicated in FIG. 1. The dummy pre-charge current source 122 is structured to provide a dummy pre-charge current to the dummy bit line 118. The dummy pre-charge current may be greater than the first data pre-charge current from the data pre-charge variable current source 112. By way of example, a ratio of the dummy pre-charge current to the first data pre-charge current may be 1.15 to 1.30.

The semiconductor device 100 includes a threshold detector 128 coupled to the dummy bit line 118. The threshold detector 128 is structured to provide a threshold signal to a threshold signal line 130 when a dummy bit line potential on the dummy bit line 118 reaches a threshold potential, relative to ground.

The semiconductor device 100 includes a pre-charge controller 132 structured to control the data pre-charge variable current source 112. The pre-charge controller 132 is connected to the threshold signal line 130, and is structured to receive the threshold signal from the threshold detector 128 on the threshold signal line 130. The pre-charge controller 132 of this example is also structured to receive a start signal from a start input node 134. The pre-charge controller 132 is structured to cause the data pre-charge variable current source 112 to provide the first data pre-charge current to the data bit line 108 after receiving the start signal and prior to receiving the threshold signal. The pre-charge controller 132 is further structured to cause the data pre-charge variable current source 112 to provide the second data pre-charge current to the data bit line 108 after receiving the threshold signal. By way of example, a ratio of the first data pre-charge current to the second data pre-charge current may be greater than 3.

The pre-charge controller 132 may also be structured to control the dummy pre-charge current source 122. In this example, the pre-charge controller 132 is structured to cause the dummy pre-charge current source 122 to provide the dummy pre-charge current to the dummy bit line 118 after receiving the start signal. In some versions of this example, the pre-charge controller 132 may be further structured to cause the dummy pre-charge current source 122 to provide a second dummy pre-charge current to the dummy bit line 118 after receiving the threshold signal. The second dummy pre-charge current is less than the dummy pre-charge current.

The semiconductor device 100 includes an impedance controller 136 that is connected to the threshold signal line 130, and is structured to receive the threshold signal from the threshold detector 128 on the threshold signal line 130. The impedance controller 136 is also structured to receive an enable signal from an enable input 138. The impedance controller 136 is further structured to control the data transfer gate 116. The enable input 138 may be implemented as a column select input from a column multiplexer, not shown, of the semiconductor device 100. The impedance controller 136 is structured to cause the data transfer gate 116 to have a first data transfer gate impedance after receiving the enable signal and prior to receiving the threshold signal. The impedance controller 136 is further structured to cause the data transfer gate 116 to have a second data transfer gate impedance after receiving the threshold signal. The second data transfer gate impedance is greater than the first data transfer gate impedance.

The semiconductor device 100 includes a sense amplifier 140 that is structured to provide a data bit output signal that corresponds to a data current line potential on the data current line 114. The data bit output signal is provided to a data bit output node 142. The sense amplifier 140 is connected to the threshold signal line 130, and is structured to receive the threshold signal from the threshold signal line 130, as depicted in FIG. 1, and to provide the data bit output signal after receiving the threshold signal. In one version of this example, the data bit output signal may be a potential at or near the operating potential used to power the sense amplifier 140 when the bit cell 104 being read is unprogrammed, and the data bit output signal may be a potential at or near ground when the bit cell 104 being read is unprogrammed. In another version of this example, the data bit output signal may be the potential at or near ground when the bit cell 104 being read is unprogrammed, and the data bit output signal may be the potential at or near the operating potential when the bit cell 104 being read is unprogrammed.

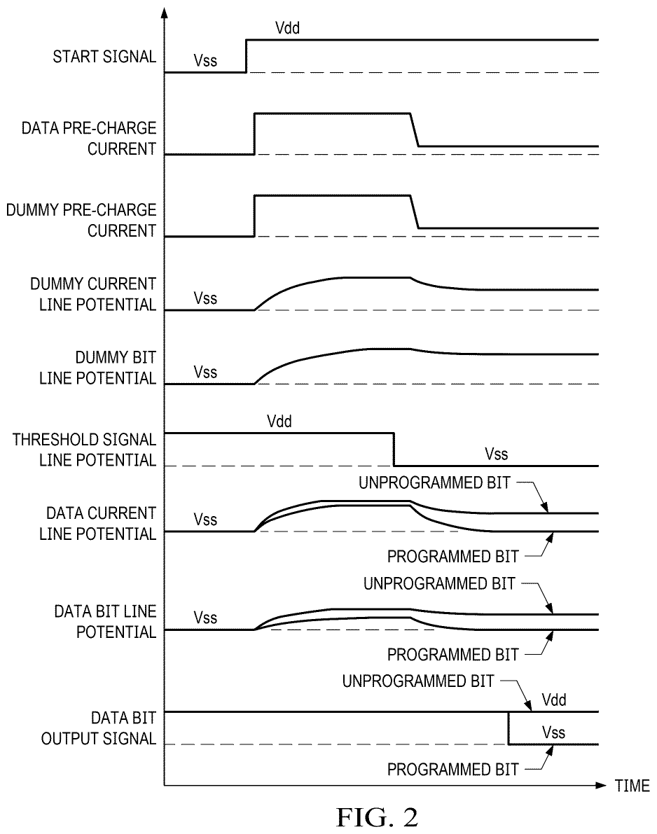

FIG. 2 is a chart of currents and potentials versus time for the semiconductor device of FIG. 1. Operation of the semiconductor device 100 is described with reference to FIG. 1 and FIG. 2. During operation of the semiconductor device 100, the data bit line 108, the data current line 114, the dummy bit line 118, and the dummy current line 124 may be held at the ground potential Vss before reading a selected bit cell 104, as shown in FIG. 2. The timeline for the data bit line potential is labeled “DATA BIT LINE POTENTIAL” in FIG. 2. The timeline for the data current line potential is labeled “DATA CURRENT LINE POTENTIAL” in FIG. 2. The timeline for the dummy bit line potential is labeled “DUMMY BIT LINE POTENTIAL” in FIG. 2. The timeline for the dummy current line potential is labeled “DUMMY CURRENT LINE POTENTIAL” in FIG. 2.

The potential of the threshold signal line 130 may be held at an operational bias potential, commonly referred to as Vdd, before reading the selected bit cell 104, as shown in FIG. 2. The timeline for the potential of the threshold signal line 130, is labeled “THRESHOLD SIGNAL LINE POTENTIAL” in FIG. 2.

The pre-charge controller 132 may cause the data pre-charge variable current source 112 and the dummy pre-charge current source 122 to be turned off, that is, to provide no substantial current, above transistor leakage current, to the data bit line 108 and the dummy bit line 118, respectively, prior to starting a read operation, as shown in FIG. 2. The timeline for the data pre-charge current is labeled “DATA PRE-CHARGE CURRENT” in FIG. 2. The timeline for the dummy pre-charge current is labeled “DUMMY PRE-CHARGE CURRENT” in FIG. 2.

To start a read operation, the passgate switch 106 of the bit cell 104 being read is set to the ON state. The passgate switches 106 of the bit cells 104 that are not being read (during the current read operation) are set to the OFF state. The impedance controller 136 causes the data transfer gate 116 to have the first data transfer gate impedance.

Subsequently, a start signal from the start input node 134 is input to the pre-charge controller 132. The timeline for the start signal is labeled “START SIGNAL” in FIG. 2. The start signal may be implemented as a change of potential at the start input node 134 from the ground potential Vss to the operational bias potential Vdd, as depicted in FIG. 2. After receiving the start signal, the pre-charge controller 132 causes the data pre-charge variable current source 112 to provide the first data pre-charge current to the data bit line 108 through the data current line 114 and the data transfer gate 116, and causes the dummy pre-charge current source 122 to provide the dummy pre-charge current to the dummy bit line 118 through the dummy current line 124 and the dummy transfer gate 126.

The first data pre-charge current flowing to the data bit line 108 causes the data bit line potential on the data bit line 108 to rise. In the case that the bit cell 104 being read is unprogrammed, the data bit line potential on the data bit line 108 will rise as the first data pre-charge current charges up the capacitance of the data bit line 108. In the case that the bit cell 104 being read is programmed, the data bit line potential on the data bit line 108 will rise at a slower rate than the unprogrammed case, because a portion of the first data pre-charge current is drained off through the programmed bit cell 104a to the reference line 110 connected to ground. The data current line potential on the data current line 114 rises more quickly than the data bit line potential on the data bit line 108, due to a potential drop across the data transfer gate 116.

The dummy pre-charge current flowing to the dummy bit line 118 causes the dummy bit line potential on the dummy bit line 118 to rise, as the dummy pre-charge current charges up the capacitance of the dummy bit line 118. In versions of this example in which the dummy bit cell 120 has a structure similar to the unprogrammed bit cells 104b, the dummy pre-charge current is not drained off by the dummy bit cell 120. In versions of this example in which the dummy bit line 118 has a resistance, a capacitance, and an inductance similar to the data bit line 108, and in which the dummy pre-charge current is greater than the first data pre-charge current, the dummy bit line potential on the dummy bit line 118 rises more quickly than the data bit line potential on the data bit line 108, whether the bit cell 104 being read is programmed or unprogrammed. A dummy current line potential on the dummy current line 124 rises more quickly than the dummy bit line potential on the dummy bit line 118, due to a potential drop across the dummy transfer gate 126.

When the dummy bit line potential on the dummy bit line 118 reaches a threshold potential of the threshold detector 128, the threshold detector 128 provides the threshold signal to the pre-charge controller 132, to the impedance controller 136, and to the sense amplifier 140. The timeline for the threshold signal is labeled “THRESHOLD SIGNAL” in FIG. 2. The threshold signal may be implemented as a transition from the operational bias potential Vdd to the ground potential Vss, as depicted in FIG. 2.

After the pre-charge controller 132 receives the threshold signal, the pre-charge controller 132 causes the data pre-charge variable current source 112 to provide the second data pre-charge current to the data bit line 108 through the data current line 114 and the data transfer gate 116. After the impedance controller 136 receives the threshold signal, the impedance controller 136 causes the data transfer gate 116 to have the second data transfer gate impedance. The second data pre-charge current being less than the first data pre-charge current, and the second data transfer gate impedance being greater than the first data transfer gate impedance, cause the data bit line potential on the data bit line 108 to rise more slowly than before the threshold detector 128 provided the threshold signal.

In some versions of this example, the pre-charge controller 132 may cause the dummy pre-charge current source 122 to provide a lower dummy pre-charge current after the threshold signal is received. The lower dummy pre-charge current may be comparable to the second data pre-charge current.

Reception of the threshold signal causes the sense amplifier 140 to process the data current line potential on the data current line 114 and provide the data bit output signal to the data bit output node 142. The timeline for the data bit output signal is labeled “DATA BIT OUTPUT SIGNAL” in FIG. 2. Having the threshold detector 128 provide the threshold signal which initiates provision of the data bit output signal may advantageously reduce a read time from the start signal to availability of the data bit output signal, compared to other read circuitry using preset delay times. Having the dummy bit line 118 with a resistance, a capacitance, and an inductance similar to the data bit line 108 may advantageously enable the threshold detector 128 to provide the threshold signal when the data current line potential on the data current line 114 has sufficient signal, that is, a potential difference between programmed bit cells 104a and unprogrammed bit cells 104b, to enable the sense amplifier 140 to reliably provide the data bit output signal with a minimal error rate. Having the ratio of the dummy pre-charge current to the first data pre-charge current at 1.15 to 1.30 may further advantageously reduce the read time by charging the capacitance on the dummy bit line 118 more quickly.

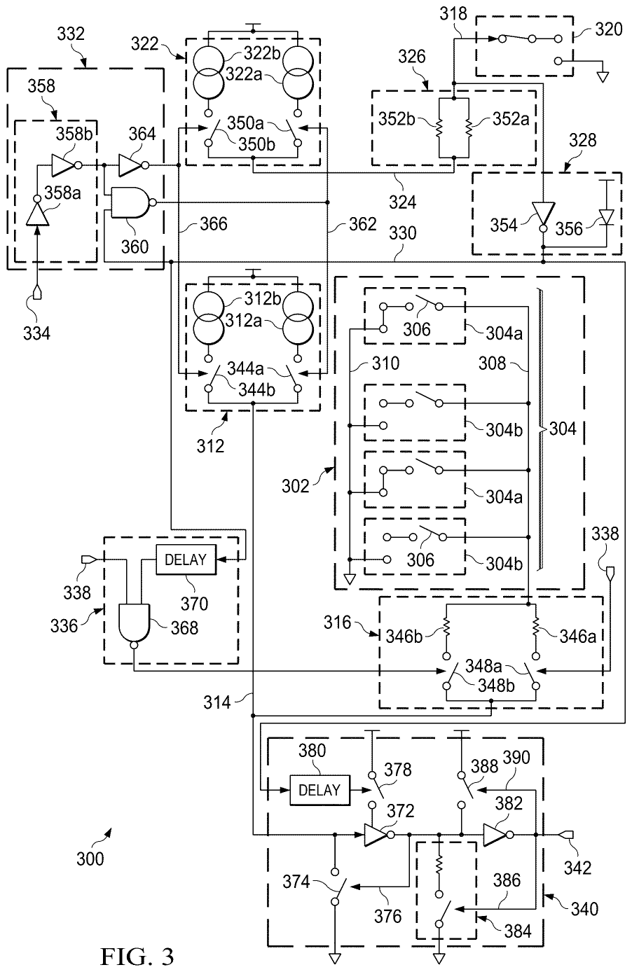

FIG. 3 is a schematic diagram of another example semiconductor device. The semiconductor device 300 includes a memory array 302 having a column of bit cells 304. Each bit cell 304 has a passgate switch 306 connected to a data bit line 308. One or more of the bit cells 304a are programmed, in which the data bit line 308 is coupled through the passgate switch 306 of that bit cell 304a to a reference line 310. The reference line 310 may be implemented as a ground line, as depicted schematically in FIG. 3. The remaining bit cells 304b are unprogrammed, in which the data bit line 308 is isolated from the reference line 310 through the unprogrammed bit cells 304b.

The semiconductor device 300 includes a data pre-charge variable current source 312 coupled to the data bit line 308. The data pre-charge variable current source 312 of this example includes a first data pre-charge current source 312a in parallel with a second data pre-charge current source 312b. The first data pre-charge current source 312a is connected in series with a first data current switch 344a. The second data pre-charge current source 312b is connected in series with a second data current switch 344b. The data pre-charge variable current source 312 is structured to provide a first data pre-charge current to the data bit line 308 when the first data current switch 344a is in the ON state and the second data current switch 344b is in the ON state, enabling both the first data pre-charge current source 312a and the second data pre-charge current source 312b to provide current to the data bit line 308. The data pre-charge variable current source 312 is structured to provide a second data pre-charge current to the data bit line 308 when the first data current switch 344a is in the OFF state and the second data current switch 344b is in the ON state, enabling only the second data pre-charge current source 312b to provide current to the data bit line 308. The second data pre-charge current is less than the first data pre-charge current. In this example, the first data current switch 344a and the second data current switch 344b may have negative transconductances; a control potential at an operational bias potential Vdd applied to control nodes of the first data current switch 344a and the second data current switch 344b causes the first data current switch 344a and the second data current switch 344b to be in the OFF states, and a control potential at the ground potential Vss applied to the control nodes of the first data current switch 344a and the second data current switch 344b causes the first data current switch 344a and the second data current switch 344b to be in the ON states.

The data pre-charge variable current source 312 is coupled to the data bit line 308 through a data current line 314 in series with a data transfer gate 316, as depicted in FIG. 3. The data transfer gate 316 of this example includes a first data impedance 346a in series with a first transfer switch 348a. In this example, the first transfer switch 348a may have a positive transconductance. The data transfer gate 316 of this example includes a second data impedance 346b in series with a second transfer switch 348b. In this example, the second transfer switch 348b may have a negative transconductance. The first data impedance 346a and the first transfer switch 348a are connected in parallel with the second data impedance 346b and the second transfer switch 348b. When the first transfer switch 348a and the second transfer switch 348b are both in ON states, the data transfer gate 316 has a first data transfer gate impedance, which is primarily a parallel combination of the first data impedance 346a and the second data impedance 346b. When the first transfer switch 348a is in the OFF state while the second transfer switch 348b is in the ON state, the data transfer gate 316 has a second data transfer gate impedance, which is primarily the second data impedance 346b. The second data transfer gate impedance is greater than the first data transfer gate impedance.

The semiconductor device 300 also includes a dummy bit line 318. The dummy bit line 318 may have a resistance, a capacitance, and an inductance similar to the data bit line 308. The semiconductor device 300 of this example includes a dummy bit cell 320 coupled to the dummy bit line 318. The dummy bit cell 320 has a structure similar to the unprogrammed bit cells 304b, that is, the dummy bit line 318 is isolated from a reference line, such as the reference line 310, through the dummy bit cell 320.

The semiconductor device 300 includes a dummy pre-charge current source 322 coupled to the dummy bit line 318. The dummy pre-charge current source 322 of this example includes a first dummy pre-charge current source 322a in parallel with a second dummy pre-charge current source 322b. The first dummy pre-charge current source 322a is connected in series with a first dummy current switch 350a. The second dummy pre-charge current source 322b is connected in series with a second dummy current switch 350b. The dummy pre-charge current source 322 is structured to provide a first dummy pre-charge current to the dummy bit line 318 when the first dummy current switch 350a is in the ON state and the second dummy current switch 350b is in the ON state, enabling both the first dummy pre-charge current source 322a and the second dummy pre-charge current source 322b to provide current to the dummy bit line 318. The dummy pre-charge current source 322 is structured to provide a second dummy pre-charge current to the dummy bit line 318 when the first dummy current switch 350a is in the OFF state and the second dummy current switch 350b is in the ON state, enabling only the second dummy pre-charge current source 322b to provide current to the dummy bit line 318. The second dummy pre-charge current is less than the first dummy pre-charge current. The first dummy pre-charge current may be greater than the first data pre-charge current. A ratio of the first dummy pre-charge current to the first data pre-charge current may be 1.15 to 1.30. In this example, the first dummy current switch 350a and the second dummy current switch 350b may have negative transconductances; a control potential at an operational bias potential Vdd applied to control nodes of the first dummy current switch 350a and the second dummy current switch 350b causes the first dummy current switch 350a and the second dummy current switch 350b to be in the OFF states, and a control potential at the ground potential Vss applied to the control nodes of the first dummy current switch 350a and the second dummy current switch 350b causes the first dummy current switch 350a and the second dummy current switch 350b to be in the ON states.

The dummy pre-charge current source 322 is coupled to the dummy bit line 318 through a dummy current line 324 in series with a dummy transfer gate 326, as indicated in FIG. 3. The dummy transfer gate 326 of this example includes a first dummy impedance 352a in parallel with a second dummy impedance 352b. The first dummy impedance 352a and the first data impedance 346a may have similar impedances, and the second dummy impedance 352b and the second data impedance 346b may have similar impedances. The first dummy impedance 352a and the second dummy impedance 352b may be fixed impedances, that is, the dummy transfer gate 326 may be structured to provide a constant impedance of the dummy transfer gate 326 during operation of the semiconductor device 300, as indicated schematically in FIG. 3. In an alternate version of this example, the dummy transfer gate 326 may have a structure similar to the data transfer gate 316.

The semiconductor device 300 includes a threshold detector 328. An input of the threshold detector 328 is coupled to the dummy bit line 318. The threshold detector 328 is structured to provide a threshold signal to a threshold signal line 330 when a dummy bit line potential on the dummy bit line 318 reaches a threshold potential, relative to ground. The threshold detector 328 may include a threshold inverter 354. An input of the threshold inverter 354 is the input of the threshold detector 328, connected to the dummy bit line 318. An output of the threshold inverter 354 is connected to the threshold signal line 330. The threshold detector 328 may further include a threshold detector diode 356 connected between a power line and the threshold signal line 330. The threshold detector diode 356 may provide a weak pullup of the threshold signal line 330 until the threshold inverter 354 pulls the threshold signal line 330 to a low reference potential, such as ground, when the dummy bit line potential on the dummy bit line 318 reaches the threshold potential.

The semiconductor device 300 includes a pre-charge controller 332. The pre-charge controller 332 of this example is structured to control the data pre-charge variable current source 312 and to control the dummy pre-charge current source 322. The pre-charge controller 332 is structured to receive the threshold signal from the threshold detector 328 through the threshold signal line 330, and to receive a start signal from a start input node 334. The pre-charge controller 332 is structured to cause both the first data current switch 344a and the second data current switch 344b of the data pre-charge variable current source 312 to be switched to ON states to provide the first data pre-charge current to the data bit line 308, after receiving the start signal and prior to receiving the threshold signal. The pre-charge controller 332 is further structured to cause the first data current switch 344a to be switched to the OFF state while maintaining the second data current switch 344b in the ON state to provide the second data pre-charge current to the data bit line 308, after subsequently receiving the threshold signal.

The pre-charge controller 332 may also be structured to control the dummy pre-charge current source 322 in a similar manner. In this example, the pre-charge controller 332 is structured to cause both the first dummy current switch 350a and the second dummy current switch 350b of the dummy pre-charge current source 322 to be switched to ON states to provide the first dummy pre-charge current to the dummy bit line 318, after receiving the start signal and prior to receiving the threshold signal. The pre-charge controller 332 is further structured to cause the first dummy current switch 350a to be switched to the OFF state while maintaining the second dummy current switch 350b in the ON state to provide the second data pre-charge current to the dummy bit line 318, after receiving the threshold signal.

The pre-charge controller 332 may include a controller delay gate 358 coupled to the start input node 334, structured to delay the start signal. The controller delay gate 358 may include a first delay inverter 358a in series with a second delay inverter 358b, as depicted in FIG. 3. The pre-charge controller 332 may include a controller logic gate 360 connected between the controller delay gate 358 and a first current switch line 362. The controller logic gate 360 may be implemented as a NAND gate, as depicted schematically in FIG. 3. The controller delay gate 358 may provide one input to the controller logic gate 360, and the threshold signal line 330 may provide another input to the controller logic gate 360. The first current switch line 362 is connected to control nodes, such as gates, of the first data current switch 344a and the first dummy current switch 350a.

The pre-charge controller 332 may include a controller inverter 364 connected between the controller delay gate 358 and a second current switch line 366. The second current switch line 366 is connected to control nodes, such as gates, of the second data current switch 344b and the second dummy current switch 350b.

The semiconductor device 300 of this example includes an impedance controller 336 that is structured to receive the threshold signal from the threshold detector 328 through the threshold signal line 330 and to receive an enable signal from an enable input 338. The enable input 338 may be implemented as a column select input from a column multiplexer, not shown, of the semiconductor device 300. The impedance controller 336 may include a delay gate 370, labeled “DELAY” in FIG. 3, connected to the threshold signal line 330. The impedance controller 336 may further include a logic gate 368 having inputs connected to the delay gate 370 and to the enable input 338. The logic gate 368 may be implemented as a NAND gate, as depicted schematically in FIG. 3. An output of the logic gate 368 is connected to a control node, such as a gate, of the second transfer switch 348b of the data transfer gate 316. The enable input 338 is connected to a control node, such as a gate, of the first transfer switch 348a of the data transfer gate 316. The impedance controller 336 is structured to cause the second transfer switch 348b to be in the ON state after the enable input 338 provides the operational bias potential Vdd and before the threshold signal is received. The impedance controller 336 is further structured to cause the second transfer switch 348b to be in the OFF state after the threshold signal is received and after a signal delay through the delay gate 370 of the impedance controller 336.

The semiconductor device 300 includes a sense amplifier 340 having a signal input connected to the data current line 314. The sense amplifier 340 has a data bit output node 342. The sense amplifier 340 of this example includes an input inverter stage 372 having a signal input coupled to the data bit line 308 through the data current line 314 and the data transfer gate 316. The sense amplifier 340 includes a first pulldown switch 374 that couples the signal input to a reference line such as Vss. The first pulldown switch 374 has a positive transconductance. The input inverter stage 372 has an output that is coupled to a control node, such as a gate, of the first pulldown switch 374 through a first feedback connection 376. A combination of the first pulldown switch 374 and the first feedback connection 376 provide a positive feedback loop for the input inverter stage 372.

The sense amplifier 340 may include an enable switch 378 connecting the input inverter stage 372 to a power line. A control node, such as a gate, of the enable switch 378 is coupled to the threshold signal line 330. The enable switch 378 is structured to be in the ON state after the threshold signal is received at the control node. The threshold signal line 330 may be coupled to the control node of the enable switch 378 through an enable delay gate 380, labeled “DELAY” in FIG. 3.

The sense amplifier 340 of this example includes an output inverter stage 382 having a digital input coupled to the signal output of the input inverter stage 372. The output inverter stage 382 has a data output connected to the data bit output node 342. The sense amplifier 340 includes a weak holding shunt 384 connected between the signal output of the input inverter stage and a reference line, such as a ground line. The sense amplifier 340 includes a second feedback connection 386 that couples the data output of the output inverter stage 382 to a control node of the weak holding shunt 384. The weak holding shunt 384 has a positive transconductance, thus, a combination of the second feedback connection 386 and the weak holding shunt 384 provides a positive feedback loop for the output inverter stage 382.

The sense amplifier 340 may further include pullup switch 388 that couples the digital input of the output inverter stage 382 to a power line. The pullup switch 388 has a negative transconductance. The sense amplifier 340 also includes a third feedback connection 390 that couples the data output of the output inverter stage 382 to a control node of the pullup switch 388. A combination of the third feedback connection 390 and the pullup switch 388 provides another positive feedback loop for the output inverter stage 382.

Operation of the semiconductor device 300 proceeds similarly to operation of the semiconductor device 100, disclosed above. Prior to reading a selected bit cell 304, the data bit line 308, the data current line 314, the dummy bit line 318, and the dummy current line 324 may be held at the ground potential Vss. The dummy bit line 318 at the ground potential Vss causes the threshold inverter 354 to hold the threshold signal line 330 at an operational bias potential Vdd. The threshold detector diode 356 provides a weak pullup of the threshold signal line 330 toward the operational bias potential Vdd, reinforcing the threshold inverter 354.

Prior to reading the selected bit cell 304, a potential on the start input node 334 may be at the ground potential Vss, causing an output of the first delay inverter 358a of the controller delay gate 358 in the pre-charge controller 332 to be at the operational bias potential Vdd, which in turn causes an output of the second delay inverter 358b of the controller delay gate 358 to be at the ground potential Vss. The threshold signal line 330 at the operational bias potential Vdd and the output of the second delay inverter 358b at the ground potential Vss causes an output of the controller logic gate 360 to be at the operational bias potential Vdd, by operation of the controller logic gate 360 as a NAND gate. The output of the controller logic gate 360 at the operational bias potential Vdd, connected to the first current switch line 362, causes the first data current switch 344a and the first dummy current switch 350a to be in the OFF states, by operation of the negative transconductances of the first data current switch 344a and the first dummy current switch 350a. The output of the second delay inverter 358b at the ground potential Vss causes an output of the controller inverter 364 to be at the operational bias potential Vdd. The output of the controller inverter 364 connected to the second current switch line 366 causes the second data current switch 344b and the second dummy current switch 350b to be in the OFF states, by operation of the negative transconductances of the second data current switch 344b and the second dummy current switch 350b. Thus, the data pre-charge variable current source 312 and the dummy pre-charge current source 322 are turned off, and provide no substantial current, above transistor leakage current, to the data bit line 308 and the dummy bit line 318, respectively.

Prior to reading the selected bit cell 304, a potential at the enable input 338 set to the operational bias potential Vdd, causing the first transfer switch 348a of the data transfer gate 316 to be in the ON state. The potentials at the enable input 338 and the threshold signal line 330 both being at the operational bias potential Vdd causes an output of the logic gate 368 of the impedance controller 336 to be at the ground potential Vss. The output of the logic gate 368 at the ground potential Vss, causes the second transfer switch 348b of the data transfer gate 316 to be in the ON state. The first transfer switch 348a and the second transfer switch 348b both being in ON states causes the data transfer gate 316 to have the first data transfer gate impedance.

Prior to reading the selected bit cell 304, the passgate switch 306 of the selected bit cell 304 being read is set to the ON state. The passgate switches 306 of the bit cells 304 that are not being read (during the current read operation) are set to the OFF state.

Subsequently, a potential at the start input node 334 is transitioned from the ground potential Vss to the operational bias potential Vdd, to initiate reading the selected bit cell 304. The potential at the start input node 334 transitioning to the operational bias potential Vdd causes the output of the second delay inverter 358b to transition to the operational bias potential Vdd, which causes the output of the controller inverter 364 and the output of the controller logic gate 360 to transition to the ground potential Vss. The output of the controller logic gate 360 transitioning to the ground potential Vss causes the potential of the first current switch line 362 to transition to the ground potential Vss, causing the first data current switch 344a and the first dummy current switch 350a to transition to the ON states. The output of the second delay inverter 358b transitioning to the ground potential Vss causes the potential of the second current switch line 366 to transition to the ground potential Vss, causing the second data current switch 344b and the second dummy current switch 350b to transition to the ON states.

The first data current switch 344a in the ON state and the second data current switch 344b in the ON state cause the data pre-charge variable current source 312 to provide the first data pre-charge current to the data bit line 308 through the data current line 314 and the data transfer gate 316. The first dummy current switch 350a in the ON state and the second dummy current switch 350b in the ON state cause the dummy pre-charge current source 322 to provide the first dummy pre-charge current to the dummy bit line 318 through the dummy current line 324 and the dummy transfer gate 326.

The first data pre-charge current flowing to the data bit line 308 causes a data bit line potential on the data bit line 308 to rise. The data bit line potential will rise more quickly in the case that the bit cell 304 being read is unprogrammed, compared to the case that the bit cell 304 being read is programmed, as explained in reference to operation of the semiconductor device 100. In both cases, a data current line potential on the data current line 314 rises more quickly than the data bit line potential on the data bit line 308, due to a potential drop across the data transfer gate 316.

The first dummy pre-charge current flowing to the dummy bit line 318 causes a dummy bit line potential on the dummy bit line 318 to rise. The dummy bit line potential may rise more quickly than the data bit line potential, depending on the magnitude of the first dummy pre-charge current relative to the first data pre-charge current, and depending on the impedance of the dummy bit line 318 relative to the impedance of the data bit line 308. The dummy current line potential on the dummy current line 324 rises more quickly than the dummy bit line potential on the dummy bit line 318, due to a potential drop across the dummy transfer gate 326. When the dummy bit line potential on the dummy bit line 318 reaches the threshold potential of the threshold detector 328, the output of the threshold inverter 354 of the threshold detector 328 overcomes the threshold detector diode 356 and transitions the potential on the threshold signal line 330 from the operational bias potential Vdd to the ground potential Vss, providing the threshold signal to the pre-charge controller 332, to the impedance controller 336, and to the sense amplifier 340. The threshold detector diode 356 may provide a desired value of the threshold potential of the threshold detector 328 be delaying the transition of the potential on the threshold signal line 330 from the operational bias potential Vdd to the ground potential Vss.

When the potential on the threshold signal line 330 transitions to the ground potential Vss, the output of the controller logic gate 360 of the pre-charge controller 332 transitions from the ground potential Vss to the operational bias potential Vdd, driving the first current switch line 362 to the operational bias potential Vdd. The first current switch line 362 at the operational bias potential Vdd causes the first data current switch 344a and the first dummy current switch 350a to transition to the OFF states, shutting off the first data pre-charge current source 312a from the data current line 314 and shutting off the first dummy pre-charge current source 322a from the dummy current line 324. The output of the controller inverter 364 of the pre-charge controller 332 is unchanged by the threshold signal from the threshold detector 328, and thus the second data current switch 344b and the second dummy current switch 350b are maintained in the ON states. Thus, after the threshold signal is provided by the threshold detector 328, the data pre-charge variable current source 312 provides the second data pre-charge current to the data bit line 308, and the dummy pre-charge current source 322 provides the second dummy pre-charge current to the dummy bit line 318. The reduced current from the data pre-charge variable current source 312 causes the data current line potential on the data current line 314 to rise more slowly.

The potential on the threshold signal line 330 transitioning to the ground potential Vss, will, after a signal delay through the delay gate 370 of the impedance controller 336, drive a first input of the logic gate 368 of the impedance controller 336 to the ground potential Vss, while a second input of the logic gate 368, connected to the enable input 338, is at the operational bias potential Vdd. The logic gate 368 is implemented in this example as a NAND gate, thus the first input at the ground potential Vss and the second input at the operational bias potential Vdd causes the output of the logic gate 368 to transition from the ground potential Vss to the operational bias potential Vdd. The output of the logic gate 368 transitioning to the operational bias potential Vdd causes the second transfer switch 348b of the data transfer gate 316 to transition to the OFF state, which causes the impedance of the data transfer gate 316 to transition from the first data transfer gate impedance to the second data transfer gate impedance.

Prior to reading the selected bit cell 304, the input inverter stage 372 of the sense amplifier 340 is not powered. The weak holding shunt 384 and the second feedback connection 386 weakly latch the digital input of the output inverter stage 382 of the sense amplifier 340 at the ground potential Vss, thus holding the data output of the output inverter stage 382 at the operational bias potential Vdd.

When the threshold potential is reached on the dummy bit line 318, the threshold signal line 330 transitioning to the ground potential Vss will, after a signal delay through the enable delay gate 380 of the sense amplifier 340, cause the enable switch 378 of the sense amplifier 340 to transition to the ON state. The enable switch 378 transitioning to the ON state provides power to the input inverter stage 372.

In the case in which the selected bit cell 304 is programmed, the potential on the data current line 314, connected to the signal input of the input inverter stage 372, is below a switching threshold of the input inverter stage 372. The input inverter stage 372 provides the operational bias potential Vdd at the signal output of the input inverter stage 372, overcoming the weak holding shunt 384. The signal output of the input inverter stage 372 at the operational bias potential Vdd causes the potential on the first feedback connection 376 to transition from the ground potential Vss to the operational bias potential Vdd, subsequently causing the first pulldown switch 374 to transition to the ON state, pulling the signal input of the input inverter stage 372 to the ground potential Vss. The input inverter stage 372 is thus latched in a high output mode, which may advantageously provide some noise immunity for the sense amplifier 340. The signal output of the input inverter stage 372, connected to the digital input of the output inverter stage 382, at the operational bias potential Vdd causes the data output of the output inverter stage 382 to transition to the ground potential Vss. The data output of the output inverter stage 382, connected to the weak holding shunt 384 through the second feedback connection 386 and connected to the pullup switch 388 through the third feedback connection 390, transitioning to the ground potential Vss causes the weak holding shunt 384 to turn off, and causes the pullup switch 388 to latch the digital input of the output inverter stage 382 at the operational bias potential Vdd. Thus, the data output of the output inverter stage 382 is latched at the ground potential Vss, for the case of reading a programmed bit cell 304a. The positive feedback loop for the output inverter stage 382 provided by the combination of the third feedback connection 390 and the pullup switch 388 may advantageously reduce a time required for the sense amplifier 340 to provide a stable data bit output signal at the data bit output node 342.

In the case in which the selected bit cell 304 is unprogrammed, the potential on the data current line 314 and the signal input of the input inverter stage 372 is above the switching threshold of the input inverter stage 372. The input inverter stage 372 provides the ground potential Vss at the signal output of the input inverter stage 372, maintaining the digital input of the output inverter stage 382 at the ground potential Vss. The first pulldown switch 374 remains in the OFF state. The data output of the output inverter stage 382 remains at the operational bias potential Vdd, causing the weak holding shunt 384 to maintain the weak pulldown, and maintaining the pullup switch 388 in the OFF state. Thus, the data output of the output inverter stage 382 is weakly latched at the operational bias potential Vdd, for the case of reading an unprogrammed bit cell 304b.

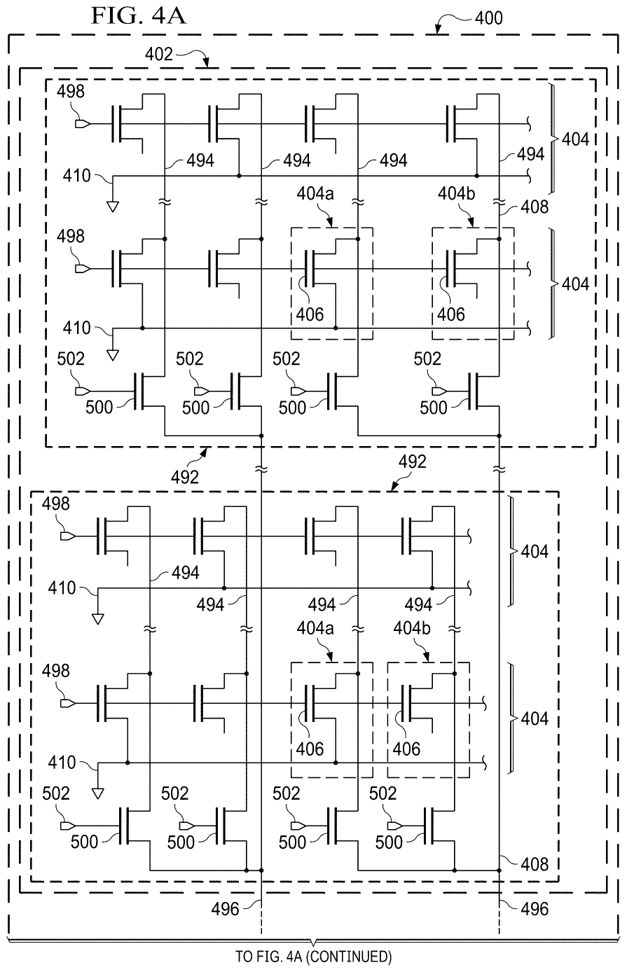

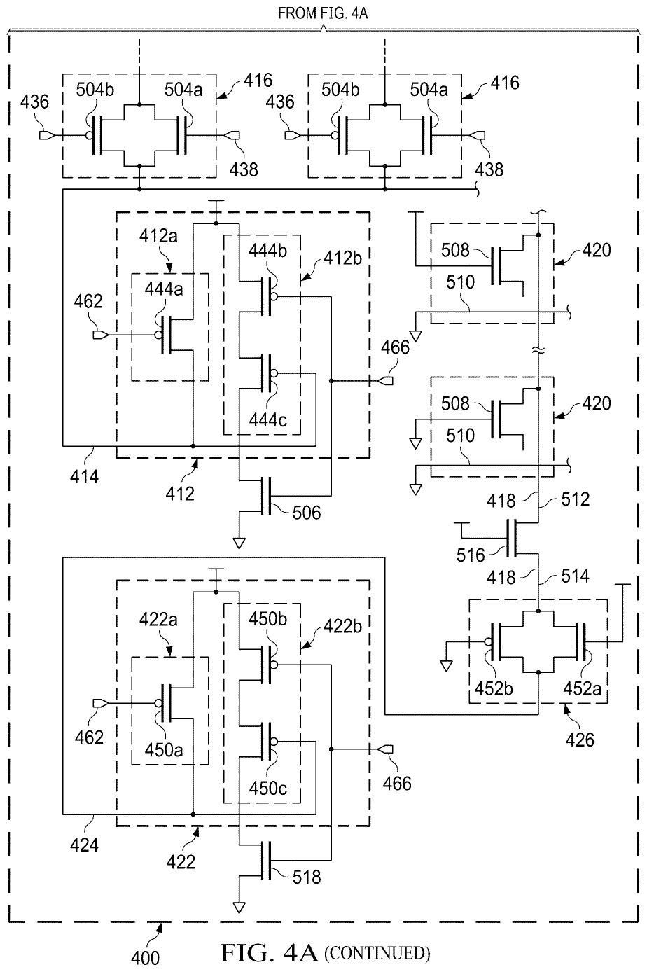

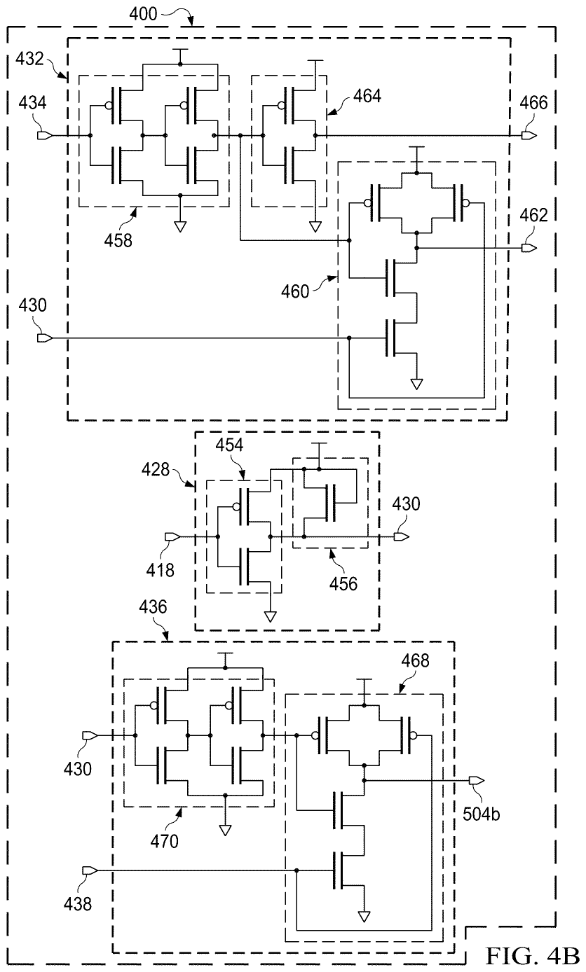

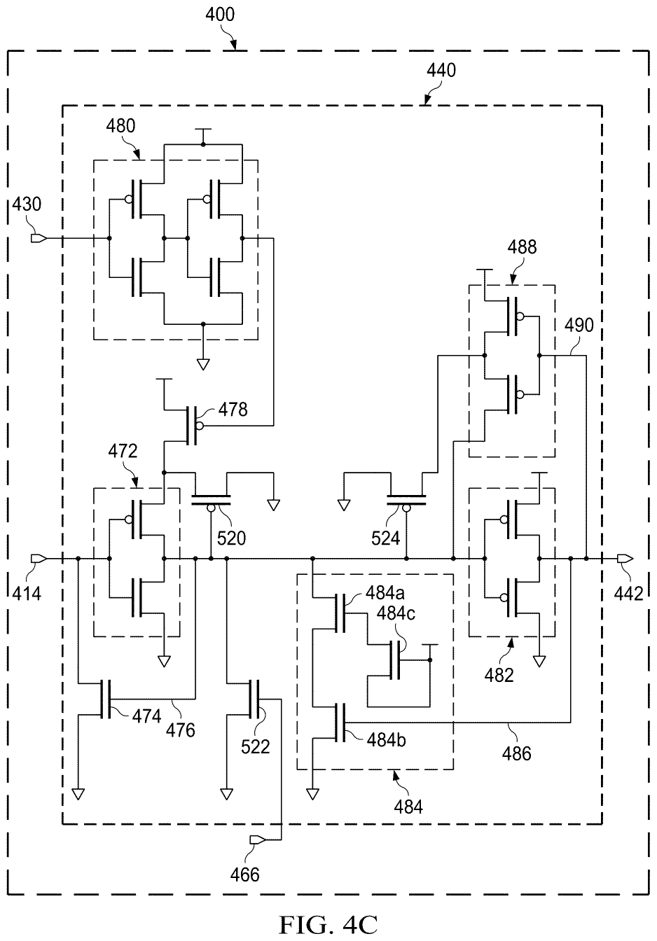

FIG. 4A through FIG. 4C are schematic diagrams of a further example semiconductor device. The semiconductor device 400 includes a memory array 402, which is implemented as a read-only memory in this example. The memory array 402 of this example includes subarrays 492, as indicated in FIG. 4A. Each subarray 492 includes bit cells 404 arrayed in rows and columns. The bit cells 404 include programmed bits cells 404a and unprogrammed bits cells 404b. Each subarray 492 includes local data bit lines 494 extending through the bit cells 404 in each column of the subarray 492, wherein each column of the bit cells 404 has a separate local data bit line 494. Each bit cell 404 has a passgate switch 406, implemented in this example as an n-channel metal oxide semiconductor (NMOS) transistor, coupled to the corresponding local data bit line 494, that is, the local data bit line 494 extending through the bit cell 404. The local data bit lines 494 may be connected to drains of the corresponding passgate switches 406.

Each subarray 492 includes a reference line 410 extending through the bit cells 404 in each row of the subarray 492. The reference line 410 may be implemented as a ground line, as depicted schematically in FIG. 4A. In each of the programmed bits cells 404a, the corresponding local data bit line 494 is coupled to the corresponding reference line 410 through the passgate switch 406 of the programmed bits cell 404a, for example, by having a source of the passgate switch 406 connected to the reference line 410. In each of the unprogrammed bits cells 404b, the corresponding local data bit line 494 is isolated from the reference line 410 by the passgate switch 406 of the programmed bits cell 404a, for example, by having a source of the passgate switch 406 unconnected to the reference line 410. Control nodes, in this example, gates, of the passgate switches 406 in each row are connected to row select lines 498. The row select lines 498 may be controlled by a row multiplexer, not specifically shown.

The memory array 402 of this example includes global data bit lines 496 extending to the subarrays 492. Each global data bit line 496 is coupled to a plurality of the local data bit lines 494 in each subarray 492 through column select switches 500. The column select switches 500 connected to each instance of the global data bit line 496 provide a column multiplexer for that global data bit line 496 to the corresponding local data bit lines 494. Control nodes 502, for example, gates, of the column select switches 500 are controlled by the column multiplexer.

Each local data bit line 494 in the memory array 402 is coupled to one of the global data bit lines 496 through one of the column select switches 500. One of the global data bit lines 496 is selected by one or more bits of the column multiplexer, and one of the local data bit lines 494 that is coupled to the selected global data bit line 496 is also selected by other bits of the column multiplexer. A combination of the selected global data bit line 496 and the selected local data bit line 494 provides a data bit line 408 of the memory array 402 for a selected bit cell 404.

Each global data bit line 496 is connected to a separate data transfer gate 416, in this example. Each data transfer gate 416 of this example includes a first switchable impedance 504a connected in parallel with a second switchable impedance 504b. The first switchable impedances 504a are implemented as NMOS transistors 504a, each of which corresponds to a combination of the first data impedance 346a and the first transfer switch 348a of FIG. 3. The second switchable impedances 504b are implemented as PMOS transistors 504b, each of which corresponds to a combination of the second data impedance 346b and the second transfer switch 348b of FIG. 3. Gates of the first switchable impedances 504a are connected to enable inputs 438 of the column multiplexer. The enable inputs 438 provide column select inputs to the first switchable impedances 504a. Gates of the second switchable impedances 504b are connected to outputs of separate impedance controllers 436, an example of which is shown in FIG. 4B.

The global data bit lines 496 are coupled through the corresponding data transfer gates 416 to a data current line 414. The data current line 414 is connected to an output of a data pre-charge variable current source 412. The data pre-charge variable current source 412 includes a first data pre-charge current source 412a in parallel with a second data pre-charge current source 412b. In this example, the first data pre-charge current source 412a may be implemented as a first current-limiting PMOS transistor 444a having a source connected to a power line and a drain connected to the data current line 414, as indicated in FIG. 4A. A gate of the first current-limiting PMOS transistor 444a is connected to a first current switch line 462. The second data pre-charge current source 412b may be implemented as a second current-limiting PMOS transistor 444b in series with a current-limiting PMOS diode 444c, connected between the power line and the data current line 414, as indicated in FIG. 4A. A gate of the second current-limiting PMOS transistor 444b is connected to a second current switch line 466. A first current source hold down NMOS transistor 506 may be connected between the data current line 414 and a reference line, as indicated in FIG. 4A, to reset the data current line 414 to ground potential prior to initiating a read operation. A gate of the first current source hold down NMOS transistor 506 may be connected to the second current switch line 466.

The semiconductor device 400 includes at least one dummy bit cell 420, and may include a column of dummy bit cells 420, as indicated in FIG. 4A. Each of the dummy bit cells 420 includes a dummy passgate switch 508, implemented as an NMOS transistor. Each of the dummy bit cells 420 includes a reference line 510 extending through the dummy bit cells 420. The semiconductor device 400 includes a local dummy bit line 512 extending through the dummy bit cells 420. Drains of the dummy passgate switches 508 are connected to the local dummy bit line 512. The dummy bit cells 420 are configured as unprogrammed, that is, sources of the dummy passgate switches 508 are not connected to the reference line 510. In one of the dummy bit cells 420, a gate of the corresponding dummy passgate switch 508 is connected to a power line, so as to be turned on during operation of the semiconductor device 400. In the remaining dummy bit cells 420, gates of the corresponding dummy passgate switches 508 are connected to a reference line, so as to be turned off during operation of the semiconductor device 400.

The memory array 402 of this example includes a global dummy bit line 514 extending to the local dummy bit line 512. The global dummy bit line 514 is coupled to the local dummy bit line 512 through a dummy column select switch 516. The dummy column select switch 516 is implemented as an NMOS transistor. A gate of the dummy column select switch 516 is connected to a power line, so as to be turned on during operation of the semiconductor device 400. A combination of the global dummy bit line 514 and the local dummy bit line 512 provides a dummy bit line 418 of the semiconductor device 400.

The global dummy bit line 514 is coupled through a dummy transfer gate 426 to a dummy current line 424, in this example. The dummy transfer gate 426 of this example includes a first dummy impedance 452a connected in parallel with a second dummy impedance 452b. The first dummy impedance 452a is implemented as an NMOS transistor 452a having a gate connected to a power line, so as to be always on during operation of the semiconductor device 400. The second dummy impedance 452b is implemented as a PMOS transistor 452b having a gate connected to a reference line, so as to be always on during operation of the semiconductor device 400.

The dummy current line 424 is connected to an output of a dummy pre-charge current source 422. The dummy pre-charge current source 422 includes a first dummy pre-charge current source 422a in parallel with a second dummy pre-charge current source 422b. In this example, the first data pre-charge current source 412a may be implemented as a first current-limiting PMOS transistor 450a having a source connected to a power line and a drain connected to the dummy current line 424, as indicated in FIG. 4A. A gate of the first current-limiting PMOS transistor 450a is connected to the first current switch line 462. The second dummy pre-charge current source 422b may be implemented as a second current-limiting PMOS transistor 450b in series with a current-limiting PMOS diode 450c, connected between the power line and the dummy current line 424, as indicated in FIG. 4A. A gate of the second current-limiting PMOS transistor 450b is connected to the second current switch line 466. A second current source hold down NMOS transistor 518 may be connected between the dummy current line 424 and a reference line, as indicated in FIG. 4A, to reset the dummy current line 424 to ground potential prior to initiating a read operation. A gate of the second current source hold down NMOS transistor 518 may be connected to the second current switch line 466.

The semiconductor device 400 includes a pre-charge controller 432 structured to receive the start signal from a start input node 434 and to receive a threshold signal from a threshold signal line 430, and to provide control signals to the first current switch line 462 and the second current switch line 466. The pre-charge controller 432 is structured to operate similarly to the pre-charge controller 332 of FIG. 3. The pre-charge controller 432 of this example includes a controller delay gate 458, implemented as a pair of inverters having PMOS pullup transistors and NMOS pulldown transistors, coupled to the start input node 434, as depicted schematically in FIG. 4B. The pre-charge controller 432 of this example includes a controller logic gate 460 implemented as a NAND gate with parallel pullup PMOS transistors and series pulldown NMOS transistors, as depicted schematically in FIG. 4B, connected between the controller delay gate 458 and the first current switch line 462. The controller delay gate 458 provides one input to one of the pullup PMOS transistors and one of the pulldown NMOS transistors, and the threshold signal line 430 provides an input to the other of the pullup PMOS transistors and the other of the pulldown NMOS transistors. The pre-charge controller 432 of this example includes a controller inverter 464, implemented as an inverter with a PMOS pullup transistor and an NMOS pulldown transistor, as depicted schematically in FIG. 4B, connected between the controller delay gate 458 and the second current switch line 466.

The semiconductor device 400 includes a threshold detector 428 connected between the dummy bit line 418, and the threshold signal line 430. The threshold detector 428 of this example includes a threshold inverter 454, implemented with a pullup PMOS transistor and a pulldown NMOS transistor, as depicted schematically in FIG. 4B. An input of the threshold inverter 454 is connected to the dummy bit line 418, and an output of the threshold inverter 454 is connected to the threshold signal line 430. The threshold detector 428 includes a threshold detector diode 456, implemented as a PMOS diode, as depicted schematically in FIG. 4B, connected between a power line and the threshold signal line 430.

The semiconductor device 400 of this example includes the impedance controller 436 that has inputs connected to the threshold signal line 430 and the enable input 438, and has an output connected to a gate of one of the second switchable impedances 504b. The impedance controller 436 includes a delay gate 470, implemented as a pair of inverters having PMOS pullup transistors and NMOS pulldown transistors, coupled to the threshold signal line 430, as depicted schematically in FIG. 4B. The impedance controller 436 further includes a logic gate 468, implemented as a NAND gate with parallel pullup PMOS transistors and series pulldown NMOS transistors, as depicted schematically in FIG. 4B. One input to the logic gate 468 is connected to an output of the delay gate 470. Another input to the logic gate 468 is connected to the enable input 438. An output of the logic gate 468 provides the output of the impedance controller 436, connected to the gate of one of the second switchable impedances 504b.

The semiconductor device 400 includes a sense amplifier 440 having an input inverter stage 472 with a signal input connected to the data current line 414. The input inverter stage 472 is implemented with a pullup PMOS transistor and a pulldown NMOS transistor, as depicted schematically in FIG. 4C. The sense amplifier 440 includes a first pulldown switch 474, implemented as an NMOS transistor, that couples the signal input to a reference line. The input inverter stage 472 has a signal output that is coupled to a gate of the first pulldown switch 474 through a first feedback connection 476, providing a positive feedback loop for the input inverter stage 472.

The sense amplifier 440 includes an enable delay gate 480, implemented as a pair of inverters having PMOS pullup transistors and NMOS pulldown transistors, as depicted schematically in FIG. 4B. An input of the enable delay gate 480 is connected to the threshold signal line 430. An output of the enable delay gate 480 is connected to a gate of an enable switch 478, implemented as a PMOS transistor. The enable switch 478 is connected between a power line and the pullup PMOS transistor of the input inverter stage 472. The sense amplifier 440 includes an input stage holding switch 520, implemented as a PMOS transistor, connected between a reference line and the pullup PMOS transistor of the input inverter stage 472. A gate of the input stage holding switch 520 is connected to the signal output of the input inverter stage 472. The sense amplifier 440 includes a pre-sensing hold down switch 522, implemented as an NMOS transistor, connected between the signal output of the input inverter stage 472 and a reference line. A gate of the pre-sensing hold down switch 522 is connected to the second current switch line 466.

The sense amplifier 440 of this example includes an output inverter stage 482 having a digital input and a data output. The output inverter stage 482 is implemented with a pullup PMOS transistor and a pulldown NMOS transistor, as depicted schematically in FIG. 4C. The digital input of the output inverter stage 482 is connected to the signal output of the input inverter stage 472. The data output of the output inverter stage 482 is connected to a data bit output node 442 of the sense amplifier 440.

The sense amplifier 440 includes a weak holding shunt 484 that connects the signal output of the input inverter stage 472 and the digital input of the output inverter stage 482 to a reference line. The weak holding shunt 484 includes a resistive load 484a, implemented as an NMOS transistor, in series with a load switch 484b, implemented as an NMOS transistor. A gate of the resistive load 484a is connected to a power line through an NMOS diode 484c of the weak holding shunt 484. A gate of the load switch 484b is connected to the data output of the output inverter stage 482 by a second feedback connection 486.

The sense amplifier 440 includes a pullup switch 488 that couples the digital input of the output inverter stage 482 to a power line. The pullup switch 488 is implemented as an upper PMOS transistor, connected to the power line, in series with a lower PMOS transistor, connected to the digital input of the output inverter stage 482. Gates of the PMOS transistors in the pullup switch 488 are connected to the data output of the output inverter stage 482 by a third feedback connection 490. The sense amplifier 440 includes a feedback holding switch 524, implemented as a PMOS transistor, that connects a source of the lower PMOS transistor in the pullup switch 488 to a reference line, as depicted schematically in FIG. 4C. A gate of the feedback holding switch 524 is connected to the digital input of the output inverter stage 482.

Operation of the semiconductor device 400 proceeds similarly to operation of the semiconductor device 100 and to operation of the semiconductor device 400, disclosed above. Prior to reading a selected bit cell 404, potentials at the enable inputs 438, the control nodes 502, and the row select lines 498 are set to the potential of the reference lines, for example, the ground potential Vss, causing the first switchable impedances 504a, the column select switches 500, and the passgate switches 406 to be in the OFF states. Potentials on the local data bit lines 494, the global data bit lines 496, the local dummy bit line 512, and the global dummy bit line 514 may be at the ground potential Vss.

The dummy bit line 418 at the ground potential Vss causes the threshold inverter 454 to hold the threshold signal line 430 at an operational bias potential Vdd. The threshold detector diode 456 provides a weak pullup of the threshold signal line 430 to an NMOS transistor threshold potential below the operational bias potential Vdd, reinforcing the threshold inverter 454.

Prior to reading the selected bit cell 404, a potential on the start input node 434 is at the ground potential Vss, causing the output of the controller delay gate 458 in the pre-charge controller 432 to be at the ground potential Vss. The threshold signal line 430 at the operational bias potential Vdd and the output of the controller delay gate 458 at the ground potential Vss causes the output of the controller logic gate 460, operating as a NAND gate, connected to the first current switch line 462, to be at the operational bias potential Vdd. The output of the first current switch line 462 at the operational bias potential Vdd causes the first current-limiting PMOS transistor 444a of the first data pre-charge current source 412a and the first current-limiting PMOS transistor 450a of the first data pre-charge current source 412a to be in OFF states. The output of the controller delay gate 458 at the ground potential Vss causes an output of the controller inverter 464, connected to the second current switch line 466, to be at the operational bias potential Vdd. The second current switch line 466 at the operational bias potential Vdd causes the second current-limiting PMOS transistor 444b and the second current limiting PMOS transistor 450b to be in the OFF states. The second current switch line 466 at the operational bias potential Vdd causes the first current source hold down NMOS transistor 506 and the second current source hold down NMOS transistor 518 to be in the ON states, holding the data current line 414 and the dummy current line 424 at the ground potential Vss.

The second current switch line 466 at the operational bias potential Vdd also causes the pre-sensing hold down switch 522 of the sense amplifier 440 to be in the ON state, which holds the signal output of the input inverter stage 472 and the digital input of the output inverter stage 482 at the ground potential Vss. The signal output of the input inverter stage 472 at the ground potential Vss causes the input stage holding switch 520 of the sense amplifier 440 to be in the ON state, thus coupling a source of the pullup PMOS transistor of the input inverter stage 472 to the ground line. The potential on the start input node 434 at the ground potential Vss causes an output of the enable delay gate 480 to be at the ground potential Vss, which causes the enable switch 478 of the sense amplifier 440 to be in the OFF state, so that the input inverter stage 472 is unpowered. The signal output of the input inverter stage 472 at the ground potential Vss causes the first pulldown switch 474 to be in the OFF state.

The output inverter stage 482 is powered, so the digital input of the output inverter stage 482 at the ground potential Vss causes the data output of the output inverter stage 482 to be at the operational bias potential Vdd. The data output of the output inverter stage 482 at the operational bias potential Vdd causes the pullup switch 488 of the sense amplifier 440 to be in the OFF state, and causes the load switch 484b of the weak holding shunt 484 to in the ON state. The digital input of the output inverter stage 482 at the ground potential Vss also causes the feedback holding switch 524 to be in the ON state.

Subsequently, the potential on the control node 502 corresponding to the selected bit cell 404 is set to the operational bias potential Vdd, causing the corresponding column select switch 500 to be in the ON state, coupling the selected local data bit line 494 to the selected global data bit line 496. A combination of the selected local data bit line 494 and the selected global data bit line 496 provides the selected data bit line 408. A potential at the enable input 438 corresponding to the selected bit cell 404 is set to the operational bias potential Vdd, causing the first switchable impedance 504a of the corresponding data transfer gate 416 to be in the ON state. The potentials at the selected enable input 438 and the threshold signal line 430 both being at the operational bias potential Vdd causes an output of the logic gate 468 of the impedance controller 436 corresponding to the selected bit cell 404 to be at the ground potential Vss, causing the second switchable impedance 504b of the corresponding data transfer gate 416 to be in the ON state, coupling the selected data bit line 408 to the data current line 414. The first switchable impedance 504a and the second switchable impedance 504b both being in ON states causes the corresponding data transfer gate 416 to have the first data transfer gate impedance. The row select line 498 corresponding to the selected bit cell 404 is set to the operational bias potential Vdd, casing the passgate switches 406 in the row containing the selected bit cell 404 to be in the ON states.

Subsequently, to initiate reading the selected bit cell 404, the potential at the start input node 434 is transitioned from the ground potential Vss to the operational bias potential Vdd. The potential at the start input node 434 transitioning to the operational bias potential Vdd causes the output of the controller delay gate 458 to transition to the operational bias potential Vdd, which causes the output of the controller inverter 464 and the output of the controller logic gate 460 to transition to the ground potential Vss. The output of the controller logic gate 460 transitioning to the ground potential Vss causes the potential of the first current switch line 462 to transition to the ground potential Vss, causing the first current-limiting PMOS transistor 444a of the first data pre-charge current source 412a and the first current-limiting PMOS transistor 450a of the first dummy pre-charge current source 422a to transition to the ON states. The output of the controller delay gate 458 transitioning to the ground potential Vss causes the potential of the second current switch line 466 to transition to the ground potential Vss, causing the second current-limiting PMOS transistor 444b of the first data pre-charge current source 412a and the second current-limiting PMOS transistor 450b to transition to the ON states. The output of the controller delay gate 458 transitioning to the ground potential Vss also causes the first current source hold down NMOS transistor 506 and the second current source hold down NMOS transistor 518 to transition to the OFF states, isolating the data current line 414 and the dummy current line 424 from the ground line.

The first current-limiting PMOS transistor 444a in the ON state and the second current-limiting PMOS transistor 444b in the ON state cause the data pre-charge variable current source 412 to provide the first data pre-charge current to the data bit line 408 through the data current line 414 and the data transfer gate 416. The first current-limiting PMOS transistor 450a in the ON state and the second current-limiting PMOS transistor 450b in the ON state cause the dummy pre-charge current source 422 to provide the first dummy pre-charge current to the dummy bit line 418 through the dummy current line 424 and the dummy transfer gate 426.

The first data pre-charge current flowing through a series impedance of the data transfer gate 416, the selected global data bit line 496, the selected column select switch 500, the selected local data bit line 494, and the selected bit cell 404 causes a data current line potential on the data current line 414 to rise. The data current line potential will rise more quickly in the case that the bit cell 404 being read is unprogrammed, compared to the case that the bit cell 404 being read is programmed, as explained in reference to operation of the semiconductor device 100.

The first dummy pre-charge current flowing through a series impedance of the dummy transfer gate 426, the global dummy bit line 514, the dummy column select switch 516, the local dummy bit line 512, and the dummy bit cell 420 causes a dummy bit line potential on the dummy bit line 418 to rise. When the dummy bit line potential on the dummy bit line 418 reaches a threshold potential of the threshold detector 428 sufficient to overcome the threshold detector diode 456, the output of the threshold inverter 454 of the threshold detector 428 causes the potential on the threshold signal line 430 to transition from the operational bias potential Vdd to the ground potential Vss, providing the threshold signal to the pre-charge controller 432, to the impedance controller 436, and to the sense amplifier 440.

When the potential on the threshold signal line 430 transitions to the ground potential Vss, the output of the controller logic gate 460 of the pre-charge controller 432 drives the first current switch line 462 to the operational bias potential Vdd. The first current switch line 462 at the operational bias potential Vdd causes the first current-limiting PMOS transistor 444a and the first current-limiting PMOS transistor 450a to transition to the OFF states, shutting off the first data pre-charge current source 412a and shutting off the first dummy pre-charge current source 422a. The second current limiting PMOS transistor 444b and the second current limiting PMOS transistor 450b remain in the ON states, and the data pre-charge variable current source 412 provides the second data pre-charge current to the data bit line 408, and the dummy pre-charge current source 422 provides the second dummy pre-charge current to the dummy bit line 418. The reduced current from the data pre-charge variable current source 412 causes the data current line potential on the data current line 414 to rise more slowly.

The threshold signal, after a signal delay through the delay gate 470 of the selected impedance controller 436, drives a first input of the logic gate 468 of the selected impedance controller 436 to the ground potential Vss, while a second input of the logic gate 468, connected to the selected enable input 438, is at the operational bias potential Vdd. The output of the logic gate 468 transitions from the ground potential Vss to the operational bias potential Vdd, causing the second switchable impedance 504b of the selected data transfer gate 416 to transition to the OFF state, which causes the impedance of the selected data transfer gate 416 to transition from the first data transfer gate impedance to the second data transfer gate impedance.

The threshold potential transitioning to the ground potential Vss, after a signal delay through the enable delay gate 480 of the sense amplifier 440, causes the enable switch 478 of the sense amplifier 440 to transition to the ON state, providing power to the input inverter stage 472. The potential of the second current switch line 466 transitioning to the ground potential Vss causes the pre-sensing hold down switch 522 to transition to the OFF state. The digital input of the output inverter stage 482 remains held at the ground potential Vss through a high impedance by the weak holding shunt 484.

In the case of the selected bit cell 404 being programmed, the potential on the data current line 414, connected to the signal input of the input inverter stage 472, is below a switching threshold of the input inverter stage 472. The input inverter stage 472 drives the signal output of the input inverter stage 472 to the operational bias potential Vdd, overcoming the weak holding shunt 484. The signal output of the input inverter stage 472 at the operational bias potential Vdd causes the first pulldown switch 474 to transition to the ON state, pulling the signal input of the input inverter stage 472 to the ground potential Vss, latching the input inverter stage 472. The signal output of the input inverter stage 472 at the operational bias potential Vdd also causes the feedback holding switch 524 and the input stage holding switch 520 to transition to the OFF states.

The signal output of the input inverter stage 472, connected to the digital input of the output inverter stage 482, being at the operational bias potential Vdd causes the data output of the output inverter stage 482 to transition to the ground potential Vss. The data output of the output inverter stage 482 transitioning to the ground potential Vss causes the weak holding shunt 484 to transition to turn off, and causes the pullup switch 488 to latch the digital input of the output inverter stage 482 at the operational bias potential Vdd. Thus, the data output of the output inverter stage 482 is latched at the ground potential Vss, for the case of reading a programmed bit cell 404a.

In the case in which the selected bit cell 404 is unprogrammed, the potential on the signal input of the input inverter stage 472 is above the switching threshold of the input inverter stage 472. The input inverter stage 472 maintains the signal output of the input inverter stage 472 and the digital input of the output inverter stage 482 at the ground potential Vss. The first pulldown switch 474 remains in the OFF state. The data output of the output inverter stage 482 remains at the operational bias potential Vdd, causing the weak holding shunt 484 to maintain the weak pulldown, and maintaining the pullup switch 488 in the OFF state. Thus, the data output of the output inverter stage 482 is weakly latched at the operational bias potential Vdd, for the case of reading an unprogrammed bit cell 404b.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and equivalents.

What is claimed is:

1. A semiconductor device, comprising:
a memory array, including bit cells and a data bit line coupled to the bit cells;
a data pre-charge variable current source coupled to the data bit line, the data pre-charge variable current source being structured to provide a first data pre-charge current to the data bit line and to provide a second data pre-charge current to the data bit line that is less than the first data pre-charge current; and
a pre-charge controller connected to the data pre-charge variable current source, the pre-charge controller being structured to:
cause the data pre-charge variable current source to provide the first data pre-charge current to the data bit line; and
subsequently cause the data pre-charge variable current source to provide the second data pre-charge current to the data bit line.

2. The semiconductor device of claim 1, wherein a ratio of the first data pre-charge current to the second data pre-charge current is greater than 3.

3. The semiconductor device of claim 1, wherein the data pre-charge variable current source includes:
a first current-limiting transistor coupled between a power line and the data bit line; and
a second current-limiting transistor, coupled between the power line and the data bit line.

4. The semiconductor device of claim 3, wherein:
the pre-charge controller is structured to cause the first current-limiting transistor and the second current-limiting transistor to transition to ON states, providing the first data pre-charge current; and
the pre-charge controller is structured to cause the first current-limiting transistor to transition to an OFF state while maintaining the second current-limiting transistor in the ON state, providing the second data pre-charge current.

5. The semiconductor device of claim 3, wherein the data pre-charge variable current source further includes a metal oxide semiconductor (MOS) diode in series with the second current-limiting transistor.

6. The semiconductor device of claim 1, further including:
a data transfer gate connecting the data bit line to the data pre-charge variable current source; and
an impedance controller coupled to the data transfer gate, the impedance controller being structured to:
cause the data transfer gate to have a first data transfer gate impedance while the data pre-charge variable current source is providing the first data pre-charge current; and
cause the data transfer gate to have a second data transfer gate impedance while the data pre-charge variable current source is providing the second data pre-charge current, wherein the second data transfer gate impedance is greater than the first data transfer gate impedance.

7. A semiconductor device, comprising:
a memory array, including bit cells and a data bit line coupled to the bit cells;
a data pre-charge current source coupled to the data bit line, the data pre-charge current source being structured to provide a data pre-charge current to the data bit line;
a dummy bit line;
a dummy pre-charge current source coupled to the dummy bit line, the dummy pre-charge current source being structured to provide a dummy pre-charge current to the dummy bit line; and
a threshold detector connected to the dummy bit line, the threshold detector being structured to provide a threshold signal a when a potential on the dummy bit line reaches a threshold potential.

8. The semiconductor device of claim 7, wherein a ratio of the dummy pre-charge current to the data pre-charge current is 1.15 to 1.30.

9. The semiconductor device of claim 7, wherein the threshold detector includes a threshold inverter having a threshold detector input coupled to the dummy bit line.

10. The semiconductor device of claim 9, wherein the threshold detector includes a threshold detector diode coupled between an output of the threshold inverter and a power line.

11. The semiconductor device of claim 10, wherein the threshold detector diode is a metal oxide semiconductor (MOS) diode.

12. The semiconductor device of claim 7, further including a pre-charge controller connected to the threshold detector and the data pre-charge current source, the pre-charge controller being structured to cause the data pre-charge current source to reduce the data pre-charge current after the threshold signal is provided by the threshold detector.

13. The semiconductor device of claim 7, further including:
a data transfer gate coupling the data bit line to the data pre-charge current source; and
an impedance controller coupled to the data transfer gate, the impedance controller being structured to:
cause the data transfer gate to have a first data transfer gate impedance prior to the threshold detector providing the threshold signal; and
cause the data transfer gate to have a second data transfer gate impedance after the threshold detector provides the threshold signal, wherein the second data transfer gate impedance is higher than the first data transfer gate impedance.

14. The semiconductor device of claim 13, wherein:
the data transfer gate includes an n-channel metal oxide semiconductor (NMOS) transfer gate transistor in parallel with a p-channel metal oxide semiconductor (PMOS) transfer gate transistor; and
the impedance controller is structured to turn off the PMOS transfer gate transistor after the threshold detector provides the threshold signal.

15. The semiconductor device of claim 7, further including a dummy transfer gate connected between the dummy pre-charge current source and the dummy bit line.

16. A semiconductor device, comprising:
a memory array, including bit cells and a data bit line connected to one of the bit cells; and
a sense amplifier, including:
an input inverter stage having a signal input and a signal output, the signal input being coupled to the data bit line;
a shunt switch having a control node, the shunt switch connecting the signal input to a reference line, the control node being structured to cause the shunt switch to vary an impedance of the shunt switch; and
a feedback connection between the signal output of the input inverter stage and the control node, wherein the feedback connection and the shunt switch provide a positive feedback loop for the input inverter stage.

17. The semiconductor device of claim 16, wherein the shunt switch has a positive transconductance.

18. The semiconductor device of claim 16, wherein the sense amplifier further includes a weak holding shunt, including:
an n-channel metal oxide semiconductor (NMOS) load transistor in series with an NMOS load switch transistor, connected between the signal output of the input inverter stage and a reference line; and
a metal oxide semiconductor (MOS) diode coupled between a gate of the NMOS load transistor and a reference line.

19. The semiconductor device of claim 16, wherein the sense amplifier further includes an output inverter stage having a digital input and a data output, the digital input being connected to the signal output of the input inverter stage.

20. The semiconductor device of claim 19, wherein a gate of the NMOS load switch transistor is connected to the data output.

21. A method of forming a semiconductor device, comprising:
forming a memory array in or over a semiconductor substrate, the memory array including bit cells and a data bit line coupled to the bit cells;
forming a data pre-charge variable current source coupled to the data bit line, the data pre-charge variable current source being structured to provide a first data pre-charge current to the data bit line and to provide a second data pre-charge current to the data bit line that is less than the first data pre-charge current; and
forming a pre-charge controller connected to the data pre-charge variable current source, the pre-charge controller being structured to:
cause the data pre-charge variable current source to provide the first data pre-charge current to the data bit line; and
subsequently cause the data pre-charge variable current source to provide the second data pre-charge current to the data bit line.
